(19) United States
(12) Patent Application Publication
(10) Pub. No.: US 2025/0273622 A1
(43) Pub. Date: Aug. 28, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Hsiang-Hua HUANG, Taichung City (TW); Mu-Hsuan CHAN, Taichung City (TW); I-Tang LIU, Taichung City (TW)

(73) Assignee: SILICONWARE PRECISION INDUSTRIES CO., LTD., Taichung City (TW)

(21) Appl. No.: 18/826,467

(22) Filed: Sep. 6, 2024

(30) Foreign Application Priority Data
Feb. 27, 2024 (TW) 113107064

(51) Int. Cl. H01L 23/00; H01L 23/31; H01L 23/498; H01L 23/538

(52) U.S. Cl. CPC H01L 24/81; H01L 23/3185; H01L 23/5385; H01L 24/16; H01L 24/32; H01L 24/73; H01L 24/83; H01L 24/92; H01L 23/49816; H01L 2224/16225; H01L 2224/32225; H01L 2224/73204; H01L 2224/81224; H01L 2224/83986; H01L 2224/9211

(57) ABSTRACT

An electronic package and a manufacturing method thereof are provided, in which an electronic element and a packaging layer encapsulating around the electronic element are disposed on a carrier structure, and the carrier structure is connected to a substrate through a plurality of solder bumps, and the electronic element is exposed by a thermal uniform interposer covering the packaging layer to irradiate the electronic element and the thermal uniform interposer with a laser beam, so that the energy of the laser beam absorbed by the thermal uniform interposer is converted into radiative heat, which is transmitted to the packaging layer below via the air, so that the solder bumps can be uniformly heated to avoid the problem of non-wetting of the solder from occurrence.

### BACKGROUND

### 1. Technical Field

The present disclosure relates to a semiconductor device, and more particularly, to a semiconductor device for improving product yield and manufacturing method thereof.

### 2. Description of Related Art

With the evolution of science and technology, the demand trend of electronic products is moving towards high end products with high density circuit/high transmission speed/high stacks/large dimension design. As the dimension of chips increases and the number contacts (I/O) increases, these products become more sensitive to thermal reactions. Therefore, thermal processes in the packaging operation, such as reflow process, easily have the overall structure cause warpage due to different coefficient of thermal expansion (CTE) between materials, and also cause poor reliability due to the concentration of thermal stress inside the structure.

As shown in FIG. 1, in the manufacturing method of conventional flip-chip semiconductor package 1, a semiconductor chip 11 is firstly bonded to a circuit structure 10 through a plurality of conductive bumps 13, then an underfill 12 is formed between the semiconductor chip 11 and the circuit structure 10 to cover the plurality of conductive bumps 13, and a packaging layer 14 is formed on the circuit structure 10 to cover the semiconductor chip 11. Afterwards, a plurality of copper pillars 100 and solder bumps 150 are formed on the lower side of the circuit structure 10, so that the circuit structure 10 is connected to a substrate 15 by the solder bumps 150.

The current method for connecting the solder bumps 150 can include a reflow method and a laser assisted bonding (LAB) method. In the LAB method, a laser beam L is mainly used for irradiation to transmit energy to the solder bumps 150, causing the solder bumps 150 to melt immediately and then harden, so that the semiconductor chip 11 is bonded to the substrate 15 by the circuit structure 10.

It is known that a conventional LAB process can be selectively heated locally and has the characteristics of rapid temperature rise, so it can shorten the time of the thermal process, thereby reducing the concentration of thermal stress inside the structure, and reducing the degree of warpage by controlling characteristics of laser wavelength and local heating.

However, in the manufacturing method of conventional semiconductor package 1, when the laser beam Lirradiates the packaging layer 14 during the LAB process, the packaging layer 14 is easy to be scorched due to overheating, causing the heat energy of the laser beam L to be transmitted to solder bumps 150 below corresponding to the packaging layer 14 is hardly to be transmitted through the circuit structure 10, so that it is easy to cause shortcomings of insufficient heat energy and solder non-wetting, as tin shrinkage or empty zin in the peripheral area B shown in FIG. 1.

Therefore, there is a need for a solution that addresses the aforementioned shortcomings in the prior art.

### SUMMARY

In view of the aforementioned shortcomings of the prior art, the present disclosure provides an electronic package, which comprises: a carrier structure; an electronic element disposed on the carrier structure; a packaging layer formed on the carrier structure for encapsulating the electronic element; a thermal uniform interposer covering the packaging layer and exposing at least a part of the electronic element; and a substrate mounted on the carrier structure via a plurality of solder bumps.

The present disclosure also provides a manufacturing method of an electronic package, which comprises: providing a carrier structure with an electronic element disposed thereon and a packaging layer encapsulating the electronic element; covering the packaging layer by a thermal uniform interposer, in a manner that at least a part of the electronic element is exposed from the thermal uniform interposer; and mounting the carrier structure on a substrate via a plurality of solder bumps, and irradiating the electronic element by a laser beam through a hollow part of the thermal uniform interposer to transmit the heat energy of the laser beam to the plurality of solder bumps.

In the aforementioned electronic package and manufacturing method thereof, the thermal uniform interposer is made from a semiconductor material.

In the aforementioned electronic package and manufacturing method thereof, the thermal uniform interposer is formed with at least a hollow part corresponding in position to the electronic element, so that the electronic element is exposed from the hollow part. For instance, the area of the hollow part is corresponding to an area of the exposed surface of the electronic element. Further, a spacing distance between the thermal uniform interposer and the packaging layer and the dimension of the hollow part are determined according to the heat energy of the laser beam irradiating the semiconductor package and an arrangement density of conductive bumps of the electronic element disposed on the carrier structure.

In the aforementioned electronic package and manufacturing method thereof, the thermal uniform interposer is disposed on the electronic element and over the carrier structure at intervals.

As can be understood from the above, in the electronic package and manufacturing method thereof of the present disclosure, by means of the arrangement of the thermal uniform interposer, the laser beam is attached to irradiate the electronic element and the carrier structure but without irradiating the packaging layer, so that the heat energy of the laser beam can be transmitted to the corresponding lower part of the packaging layer through the carrier structure, and at the same time, the thermal uniform interposer absorbs the energy of the laser beam and converts it into radiative heat, which is transmitted to the packaging layer below via the air to uniformly heat the solder bumps. Therefore, compared to the prior art, the present disclosure can not only resolve the problem that the packaging layer is easily scorched due to overheating, but also avoid the problem of solder non-wetting of the solder bumps from occurrence.

### BRIEF DESCRIPTION OF THE DRAWINGS

FIG. 1 is a schematic cross-sectional view of a conventional flip-chip semiconductor package.

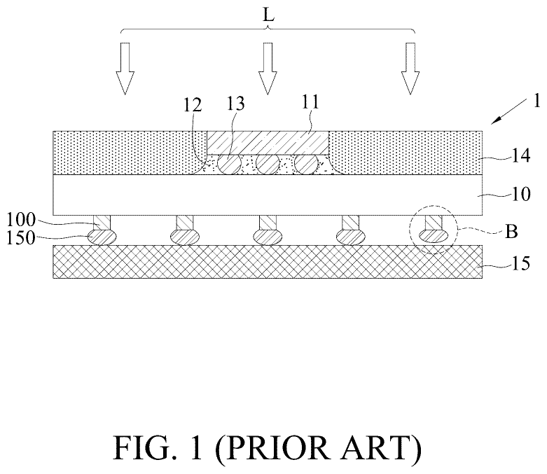

FIG. 2A to FIG. 2C are schematic cross-sectional views of a manufacturing method of an electronic package of the present disclosure.

FIG. 3A is a schematic partial top view of FIG. 2A.

FIG. 3B is a schematic partial top view of FIG. 2B.

FIG. 4 is a schematic cross-sectional view of another embodiment of an electronic package of the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” and the like are merely used for clear explanation rather than limiting the practicable scope of the present disclosure, and thus, alterations or adjustments of the relative relationships thereof without essentially altering the technical contents should still be considered in the practicable scope of the present disclosure.

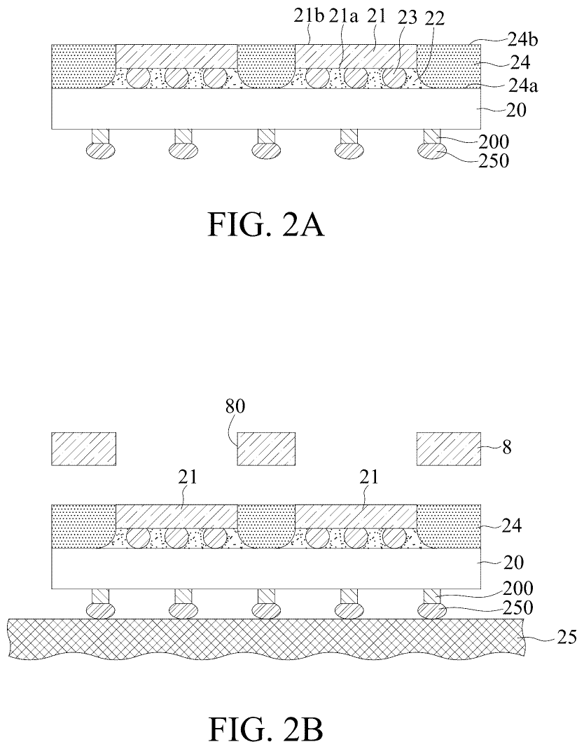

FIG. 2A to FIG. 2C are schematic cross-sectional views of a manufacturing method of an electronic package 2 of the present disclosure.

As shown in FIG. 2A, a chip package body is provided, which has a carrier structure 20 and at least one electronic element 21.

The carrier structure 20 can be, for example, a packaging substrate with a core layer and circuit structure, a packaging substrate with a coreless circuit structure, a through silicon interposer (TSI) with through-silicon vias (TSV) or other board types, which includes at least one insulating layer and at least one circuit layer bonded to the insulating layer, such as at least one fan out type redistribution layer (RDL). It should be understood that the carrier structure 20 can also be other boards for carrying chips, such as a lead frame, a wafer, or other board with metal routing, but the present disclosure is not limited to as such.

In this embodiment, there are various manufacturing process of the carrier structure 20, for example, the circuit layer can be manufactured by using wafer processes, and silicon nitride or silicon oxide can be formed through chemical vapor deposition (CVD) as an insulating layer; alternatively, a circuit layer can be formed by using general non-wafer processes, that is, a polymer dielectric material with lower cost can be used as the insulating layer, such as polyimide (PI), polybenzoxazole (PBO), prepreg (PP), molding compound, photosensitive dielectric layer or other materials formed by coating.

The electronic element 21 is disposed on an upper side of the carrier structure 20, which can be an active element, a passive element, or a combination thereof, wherein the active element is, for example, a semiconductor chip, and the passive element is, for example, a resistor, a capacitor, or an inductance.

In this embodiment, the electronic element 21 is a semiconductor chip having an active surface 21a and an inactive surface 21b opposing the active surface 21a, electrode pads of the active surface 21a are disposed on the carrier structure 20 by a plurality of conductive bumps 23 such as solder material, metal pillars, or others in a flip-chip manner, and the electrode pads of the active surface 21a are electrically connected to the circuit layer of the carrier structure 20, then an underfill 22 is formed between the electronic element 21 and the carrier structure 20 to encapsulate the conductive bumps 23; alternatively, the electronic element 21 can be electrically connected to the circuit layer of the carrier structure 20 via a plurality of bonding wires (not shown) in a wire bonding manner; or, the electronic element 21 can be in direct contact with the circuit layer of the carrier structure 20. Therefore, the required type and quantity of electronic elements can be mounted on the carrier structure 20 to improve the electrical functions thereof, and there are various ways for electrically connecting the electronic element 21 to the carrier structure 20, but the present disclosure is not limited to as such.

And then, a packaging layer 24 is formed on the carrier structure 20, such that the packaging layer 24 covers the electronic elements 21 and the underfill 22.

In this embodiment, a material forming the packaging layer 24 is made from an insulating material, such as polyimide (PI), molding compound of epoxy, which can be formed in a manner of molding, lamination, or coating.

Furthermore, the packaging layer 24 has a first surface 24a and a second surface 24b opposing the first surface 24a, and the first surface 24a is bonded to the carrier structure 20, and the inactive surface 21b of the electronic element 21 is aligned with the second surface 24b of the packaging layer 24, such that the inactive surfaces 21b of the electronic elements 21 are exposed from the second surface 24b of the packaging layer 24. Alternatively, the packaging layer can also encapsulate the inactive surface 21b of the electronic element 21, so that the second surface of the packaging layer is higher than the inactive surface 21b of the electronic element 21. It should be understood that the leveling process can be performed by grinding, cutting, or etching, etc. to obtain the aspect of the packaging layer 24 as shown in FIG. 2B.

Furthermore, a plurality of conductive elements 200 are formed on a lower side of the carrier structure 20, and a plurality of solder bumps 250 are disposed thereon as contacts. Specifically, the conductive element 200 can be a metal pillar such as a copper pillar or other conductive configurations, etc.

As shown in FIG. 2B, the carrier structure 20 is coupled to a substrate 25, and at least one thermal uniform interposer 8 is disposed over the chip package body to cover the packaging layer 24, and the thermal uniform interposer 8 has at least one hollow part 80 corresponding to the electronic element 21, such that at least part of the inactive surface 21b of the electronic element 21 is exposed from the hollow part 80.

In this embodiment, the thermal uniform interposer 8 is made from semiconductor material, such as silicon wafer, and is separated from the packaging layer 24 by a certain space.

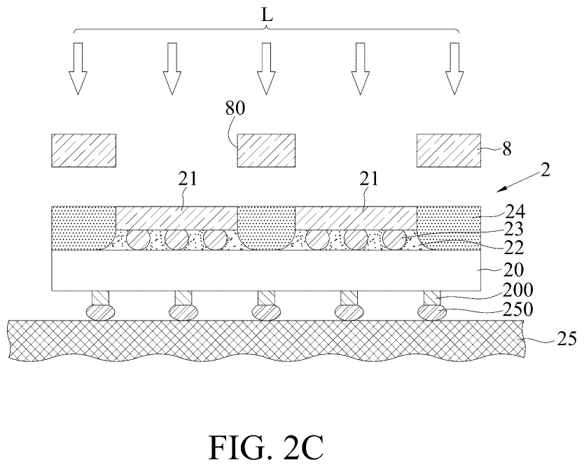

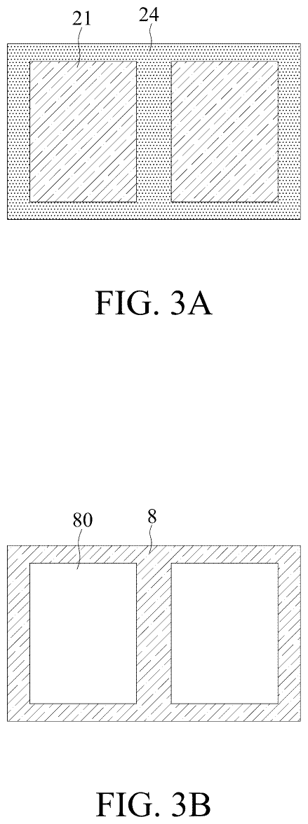

Please refer to FIG. 3A and FIG. 3B at the same time, which are schematic partial top views of FIG. 2A and FIG. 2B, the area dimension of the hollow part 80 can be the same or different, and the area of the hollow part 80 can be corresponding to (e.g., equal to or smaller than) the area of the exposed surface (e.g., the inactive surface 21b) of the electronic element 21. For instance, a projected area of the thermal uniform interposer 8 in the vertical direction is equal to a projected area of the profile of the packaging layer 24 in the vertical direction.

Furthermore, the substrate 25 can be, for example, a packaging substrate with a core layer and circuit structure, a packaging substrate with a coreless circuit structure, which comprises at least one insulating layer and at least one circuit layer bonded to the insulating layer, such as at least one fan out type redistribution layer (RDL).

As shown in FIG. 2C, laser assisted bonding (LAB) is used to have a laser beam L pass through the hollow part 80 to irradiate the electronic element 21 and carrier structure 20, so as to transmit the heat energy to the solder bumps 250 through the electronic element 21, the carrier structure 20, and the thermal uniform interposer 8, so that the electronic element 21 is bonded to the substrate 25 by the carrier structure 20.

During the application, the separating space between the thermal uniform interposer 8 and the packaging layer 24, and the dimension of the hollow part 80 can be adjusted according to the heat energy of the laser beam L and a arrangement density of the conductive bumps 23.

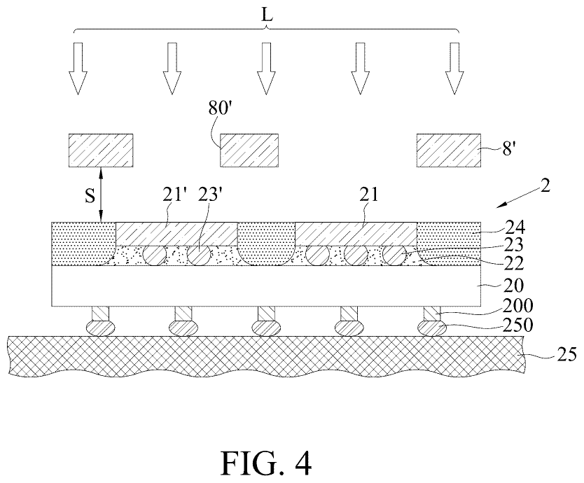

As shown in FIG. 4, in another embodiment of an electronic package 2 of the present disclosure, the separating space S between a thermal uniform interposer 8′ and the packaging layer 24 and the dimension of a hollow part 80′ can match the change of the heat energy of the laser beam L and the arrangement density of conductive bumps 23′ of an electronic element 21′ arranged on the carrier structure 20.

Therefore, the manufacturing method of the present disclosure is to use the arrangement of the thermal uniform interposer 8 to cover the laser beam L relative to the position of the packaging layer 24, so that the laser beam L passes through the hollow portion 80 to irradiate the electronic element 21 without directly irradiating the packaging layer 24, such that the heat energy of the laser beam L can be transmitted to the corresponding position below the packaging layer 24 through the carrier structure 20, and that the energy of the laser beam L absorbed by the thermal uniform interposer 8 is converted into radiant heat at the same time, which is transmitted to the packaging layer 24 below through the air, so that the solder bumps 250 can be uniformly heated. Therefore, compared to the prior art, the present disclosure can not only avoid the problem that the packaging layer 24 is easily scorched due to overheating, but also avoid the problem of solder non-wetting of the solder bumps 250.

The present disclosure also provides an electronic package 2, the electronic package 2 comprises: a carrier structure 20, at least one electronic element 21 disposed on the carrier structure 20, a packaging layer 24 disposed on the carrier structure 20 and encapsulating around the electronic element 21, a thermal uniform interposer 8 covered the packaging layer 24 and exposing at least part of the electronic element 21, and a substrate 25 connected to the carrier structure 20 by a plurality of solder bumps 250.

In an embodiment, wherein the thermal uniform interposer 8 is a semiconductor material.

In an embodiment, wherein the thermal uniform interposer 8 has at least a hollow part 80 corresponding to the electronic element 21, so that the electronic element 21 is exposed out from the hollow part 80. For instance, the area of the hollow part 80 corresponds to the area of the exposed surface of the electronic element 21.

In an embodiment, the projected area of the thermal uniform interposer 8 in the vertical direction is equal to the projected area of the profile of the packaging layer 24 in the vertical direction.

In view of the above, the electronic package and manufacturing method thereof of the present disclosure is to use the arrangement of the thermal uniform interposer to cover the laser beam, so that the laser beam only irradiates the electronic element and cannot irradiate the packaging layer, such that the heat energy of the laser beam can be transmitted to the corresponding position below the packaging layer through the carrier structure, and that the energy of the laser beam absorbed by the thermal uniform interposer is converted into radiant heat at the same time, which is transmitted to the packaging layer below through the air, so that the solder bumps can be uniformly heated to avoid the problem of non-wetting of solder bumps.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure;
an electronic element disposed on the carrier structure;
a packaging layer formed on the carrier structure for encapsulating the electronic element;
a thermal uniform interposer covering the packaging layer and exposing at least a part of the electronic element; and
a substrate connected to the carrier structure by a plurality of solder bumps.

2. The electronic package of claim 1, wherein the thermal uniform interposer is made of a semiconductor material.

3. The electronic package of claim 1, wherein the thermal uniform interposer has a hollow part corresponding in position to the electronic element, so that the electronic element is exposed from the hollow part.

4. The electronic package of claim 3, wherein an area of the hollow part corresponds to an area of a surface of the electronic element exposed from the hollow part.

5. The electronic package of claim 3, wherein a spacing distance between the thermal uniform interposer and the packaging layer and a dimension of the hollow part are determined according to heat energy of a laser beam used to irradiate the semiconductor package and an arrangement density of conductive bumps of the electronic element disposed on the carrier structure.

6. The electronic package of claim 1, wherein the thermal uniform interposer is disposed on the electronic element and over the carrier structure at intervals.

7. A method of manufacturing an electronic package, comprising:
providing a carrier structure disposed with an electronic element thereon and a packaging layer encapsulating the electronic element;
covering the packaging layer by a thermal uniform interposer, and at least part of the electronic element is exposed out from the thermal uniform interposer; and
mounting the carrier structure on a substrate via a plurality of solder bumps, and irradiating the electronic element by a laser beam through a hollow part of the thermal uniform interposer to transmit heat energy of the laser beam to the plurality of solder bumps.

8. The method of claim 7, wherein the thermal uniform interposer is formed from a semiconductor material.

9. The method of claim 7, wherein the thermal uniform interposer has at least a hollow part corresponding to the electronic element, so that the electronic element is exposed from the hollow part.

10. The method of claim 9, wherein an area of the hollow part corresponds to an area of the exposed surface of the electronic element.

11. The method of claim 9, wherein a spacing distance between the thermal uniform interposer and the packaging layer and a dimension of the hollow part are determined according to the heat energy of the laser beam and an arrangement density of conductive bumps of the electronic element disposed on the carrier structure.

12. The method of claim 7, wherein the thermal uniform interposer is disposed on the electronic element and over the carrier structure at intervals.
